(19) United States
(12) Patent Application Publication
(10) Pub. No.: US 2013/0027850 A1
(43) Pub. Date: Jan. 31, 2013

(54) EMPLACEMENT STRUCTURE FOR A TABLET PERSONAL COMPUTER

(71) Applicants: Yu Wen CHANG, Dongguan City (CN); Tracer CHOW, Naperville, IL (US); Michael FIORENTINO, Duxbury, MA (US); Dennis CAYA, Wrentham, MA (US)

(72) Inventors: Yu Wen CHANG, Dongguan City (CN); Tracer CHOW, Naperville, IL (US); Michael FIORENTINO, Duxbury, MA (US); Dennis CAYA, Wrentham, MA (US)

(73) Assignee: H20 FURNISHINGS LLC, Brookline, MA (US)

(21) Appl. No.: 13/404,322

(22) Filed: Feb. 24, 2012

(30) Foreign Application Priority Data
Jul. 28, 2011 (CN) 201120269816.6

(51) Int. Cl. H05K 7/00; A47B 83/02; A47B 37/00; F16M 11/20; F16M 11/10

(52) U.S. Cl. 361/679.01; 248/371; 248/121; 108/50.11; 297/135

(57) ABSTRACT

A emplacement structure for a tablet personal computer includes primarily a box, the box is provided with an emplacement space to put a stool and is opened with a combining slot; a cover plate, the cover plate is opened with a holding slot and a bottom of the cover plate is provided with plural positioning slots and a magnet; and a movable plate, the movable plate is provided with a movable bracket that is inserted into one of the positioning slots for positioning and is provided with a magnet. Alternatively, the movable plate may be incorporated directly into the surface of a piece of furniture such as a desk, table, stool, or workstation.

### CROSS-REFERENCE TO RELATED APPLICATIONS

The present invention claims priority to Chinese Application No. 201120269816.6, filed Jul. 28, 2011, the entire contents of which are incorporated by reference in their entirety.

### BACKGROUND OF THE INVENTION

a) Field of the Invention

The present invention relates to an emplacement structure for a tablet personal computer, and more particularly to an emplacement structure for a tablet personal computer, wherein the emplacement structure is simple and easy to operate. Through a design that combines a box, a stool and a cover plate for use, the tablet personal computer can be emplaced conveniently to facilitate use at home, and a space to be occupied can be reduced to achieve practicability. The design of the cover plate may also be incorporated into other furniture items such as desks, tables, stools, or workstations.

b) Description of the Prior Art

An ordinary computer is always put directly on an office desk and a stool is also needed when using the computer. On the other hand, when the computer is not in use, the office desk and the stool will take up a lot of space. As a result, how to reduce the space that is occupied by the office equipment so that the computer can be used more conveniently is an issue to be solved.

### SUMMARY OF THE INVENTION

Accordingly, a primary object of the present invention is to provide a three-in-one emplacement structure for a tablet personal computer to effectively solve the shortcoming that the conventional office equipment occupies a lot of space, thereby being deeply provided with practicability. Through a design that combines the box, the stool and the cover plate, this structure not only allows the tablet personal computer to be emplaced conveniently for ease of use at home, but also reduces the space to be occupied, thereby achieving practicability.

To achieve the abovementioned object, the three-in-one emplacement for a tablet personal computer, according to the present invention, includes primarily a box, the box is provided with an emplacement space to put a stool and is opened with a combining slot; a cover plate, the cover plate is put on the combining slot of the box and is opened with a holding slot, whereas a bottom of the cover plate is provided with plural positioning slots and a magnet; and a movable plate, the movable plate is put on the holding slot to move, a back side of the movable plate is provided with a movable bracket that is inserted into one of the positioning slots for positioning and is provided with a magnet combining and positioning with the magnet of the cover plate.

Through a design that combines the box, the stool and the cover plate, when the emplacement structure is in use, the stool is taken out of the box, the cover plate is turned over and put on the box as a table top, the movable plate is lifted up, the movable bracket is lifted outward by a certain angle and is then inserted into a positioning slot for positioning, and finally the tablet personal computer is put on the movable plate. On the other hand, when the emplacement structure is not in use, the stool is put into the box, the movable bracket of the movable plate is folded inward and put on the holding slot, the movable bracket is next positioned through that the magnet thereof attracts the magnet of the cover plate, and finally the cover plate is turned over and put on the combining slot of the box for positioning. This structure not only facilitates emplacing the tablet personal computer so that the tablet personal computer can be used at home easily, but also reduces the space to be occupied, thereby achieving practicability.

A second object of the present invention is to provide a three-in-one emplacement structure for a tablet personal computer, wherein the cover plate is opened with a groove to facilitate emplacing the tablet personal computer, thereby achieving practicability.

A third object of the present invention is to provide a three-in-one emplacement structure for a tablet personal computer, wherein two sides of the cover plate can be added respectively with a movable plate to increase a space of use to facilitate putting data, and each movable plate is provided with a magnet. When the emplacement structure is not in use, the movable plates are folded inward, allowing the magnets thereof to attract the magnet of the cover plate for positioning. This structure can increase utilization of the cover plate to achieve variability.

A fourth object of the present invention is to provide a three-in-one emplacement structure for a tablet personal computer, wherein a side of the box is provided with a stereo to increase an audio effect.

A fifth object of the present invention is to provide a piece of furniture such as a desk, table, or portable workstation incorporating a movable plate integrated into the surface furniture. When in a closed position, the movable plate is preferably flush with the surface of the furniture. The movable plate is pivotally attached to the surface of the furniture allowing it to move between an open position and a closed position. The backside of the movable plate is provided with a movable bracket that is inserted into one of a plurality of positioning slots.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a schematic view of the present invention after being assembled.

FIG. 2 shows an exploded view of the present invention.

FIG. 3 shows a three-dimensional schematic view of the present invention.

FIG. 4 shows a schematic view of use of the present invention.

FIG. 5 shows a schematic view of an embodiment of a cover plate of the present invention.

FIG. 6 shows a view of a desk having a movable plate.

FIG. 7 shows a view of the desk of FIG. 6 when the movable plate is in an open position.

FIG. 8 shows a side view of the desk of FIG. 6

FIG. 9 shows a front view of a workstation having a movable plate.

FIG. 10 shows a view of the workstation of FIG. 9 when the movable plate is in an open position.

FIG. 11 shows a rear view of the workstation of FIG. 9.

FIG. 12 shows a front view of the workstation of FIG. 9 having a tablet on the movable plate.

FIG. 13 shows a view of an alternative workstation having a movable plate in an open position.

FIG. 14 shows a view of a stool having a movable plate in an open position.

FIG. 15 shows a view of a table having a movable plate.

FIG. 16 shows a view of the table of FIG. 15 when the movable plate is in an open position.

FIG. 17 shows a view of an end table having a movable plate.

### DETAILED DESCRIPTION OF THE PREFERRED EMBODIMENTS

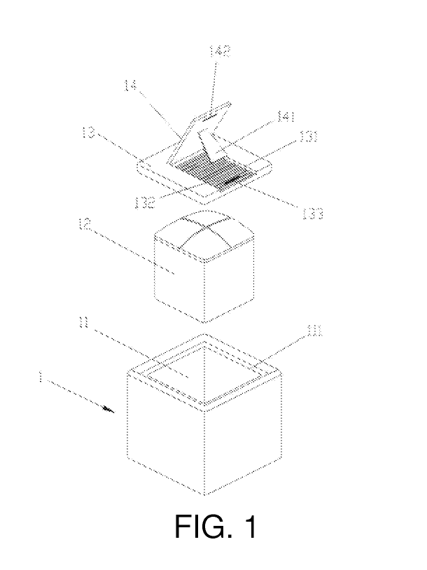

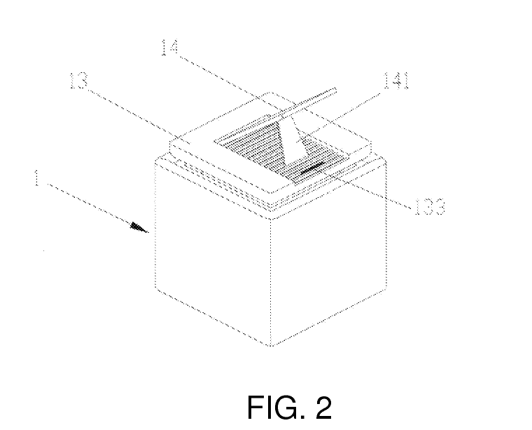

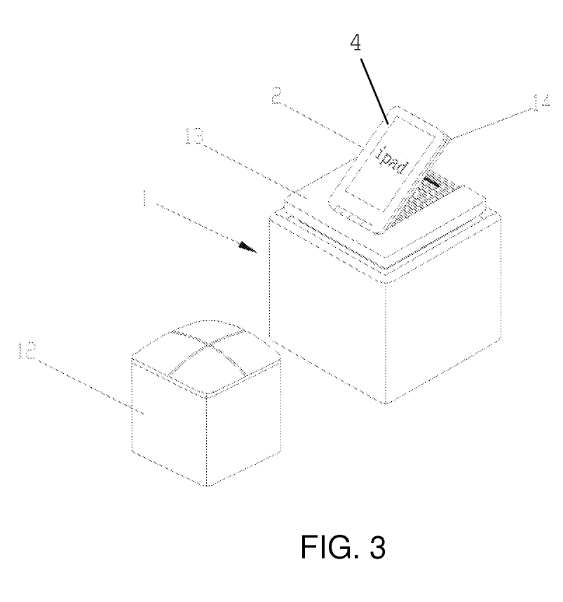

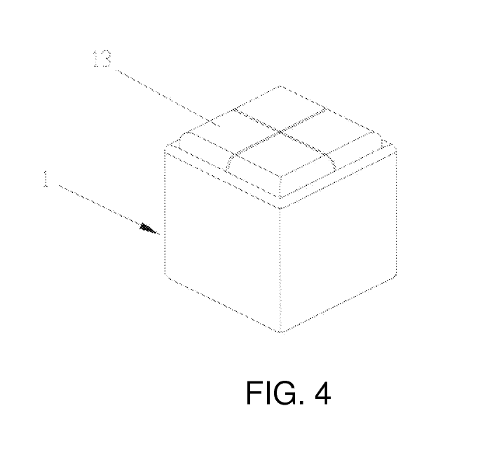

Referring to FIGS. 1 to 4, a three-in-one emplacement structure for a tablet personal computer, according to the present invention, comprises primarily a box 1, the box 1 is provided with an emplacement space 11 to put a stool 12 and is opened with a combining slot 111; a cover plate 3, the cover plate 13 is put on the combining slot 111 of the box 1 and is opened with a holding slot 131, with that a bottom of the cover plate 13 is provided with plural positioning slots 132 and a magnet 133; and a movable plate 14, the movable plate 14 is put on the holding slot 131 to move and a back side of the movable plate 14 is provided with a movable bracket 141 that is inserted into one of the positioning slots 132 for positioning and is provided with a magnet 142 combining and positioning with the magnet 133 of the cover plate 13.

By a design that combines the box 1, the stool 12 and the cover plate 13, when the present invention is in use, the stool 12 is taken out of the box 1, the cover plate 13 is turned over and put on the box 1 as a table top, the movable plate 14 is lifted up and the movable bracket 141 is lifted outward by a certain angle and is then inserted into a positioning slot 132 for positioning, and finally a tablet personal computer 4 is put on the movable plate 14. On the other hand, when the present invention is not in use, the stool 12 is put into the box 1, the movable bracket 141 of the movable plate 13 is folded inward, put on the holding slot 131 and is positioned by that the magnet 142 attracts the magnet 133 of the cover plate 13, and finally the cover plate 13 is turned over and put on the combining slot 111 of the box 1 for positioning. This structure not only allows the tablet personal computer 4 to be easily emplaced that the tablet personal computer 4 can be used easily at home, but also reduces a space to be occupied, thereby achieving practicability.

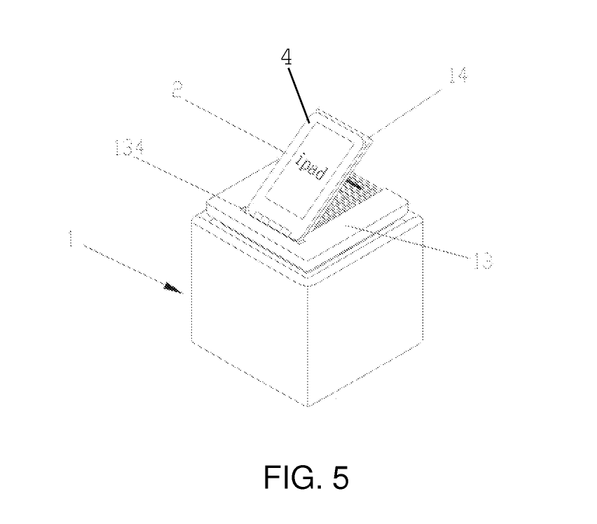

Referring to FIG. 5, the cover plate 3 can be opened with a groove 134 to facilitate emplacing the tablet personal computer 4, thereby achieving practicability. In some embodiments, the side of the box 1 can be provided with a speaker, stereo, or other audio component.

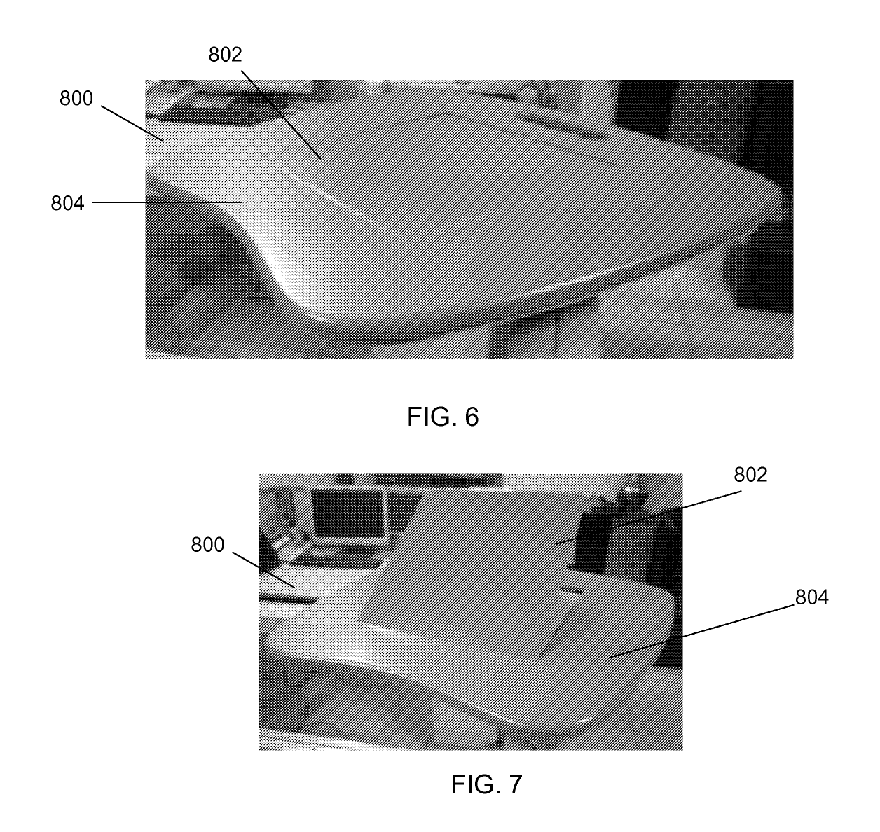

Referring to FIG. 6, shown is a view of desk 800 having movable plate 802 that resides flush with the surface 804 of desk 800 when movable plate 802 is in a closed position. The construction and arrangement of movable plate 802 is substantially similar to that of movable plate 14. Preferably, movable plate 802 is attached to desk 800 via a hinge. As shown in FIG. 7, movable plate 802 can be moved to an open position from the closed position depicted in FIG. 6.

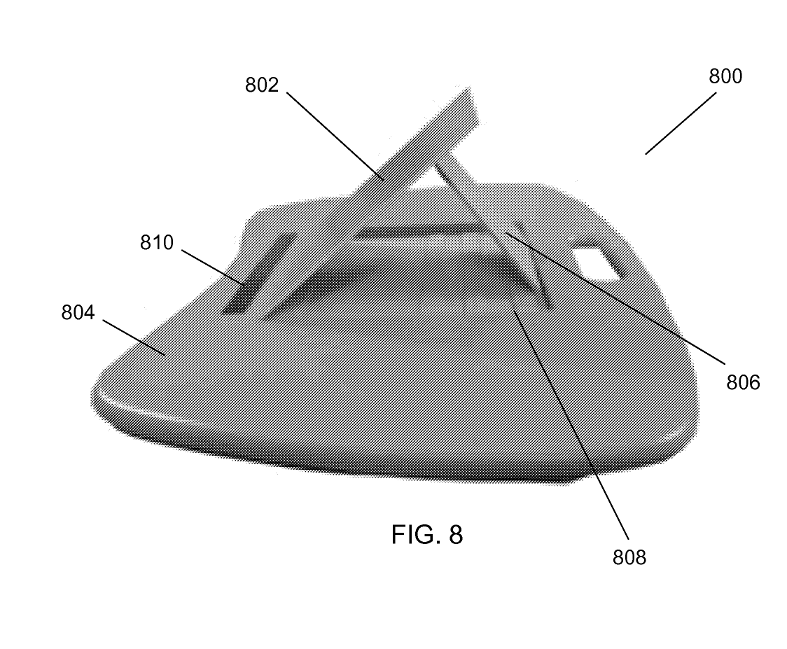

Referring now to FIG. 8, movable plate 802 is retained in its open position by movable bracket 806 that resides in positioning slots 808 which are located in the recess in which movable plate 802 resides when in the closed position. Alternatively, the positioning slots may be located on the rear surface of movable plate 802 and the movable bracket may be located in the recess. The angle of movable plate 802 with respect to surface 804 can be varied by moving movable bracket 806 between different positioning slots 808. In some embodiments, as shown in FIG. 8, surface 804 may incorporate strip 810 located at the base of movable plate 802. Preferably, strip 810 is made from a non-skid material for keeping objects placed on movable plate 802 from sliding off. Strip 810 may also be a recessed slot, a raised strip, or other equivalent structure.

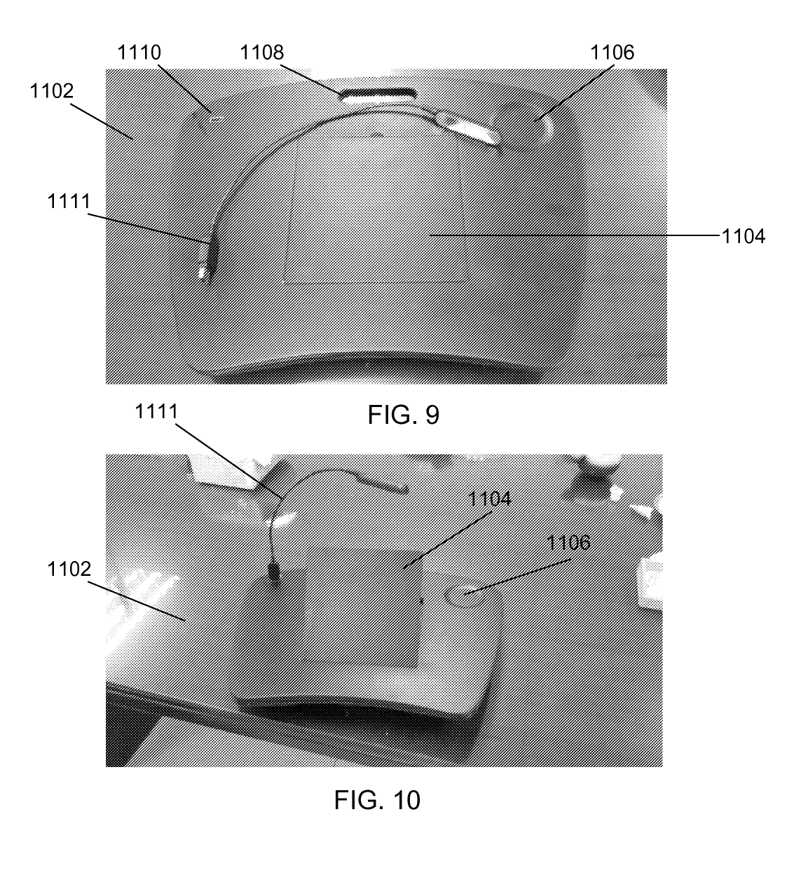

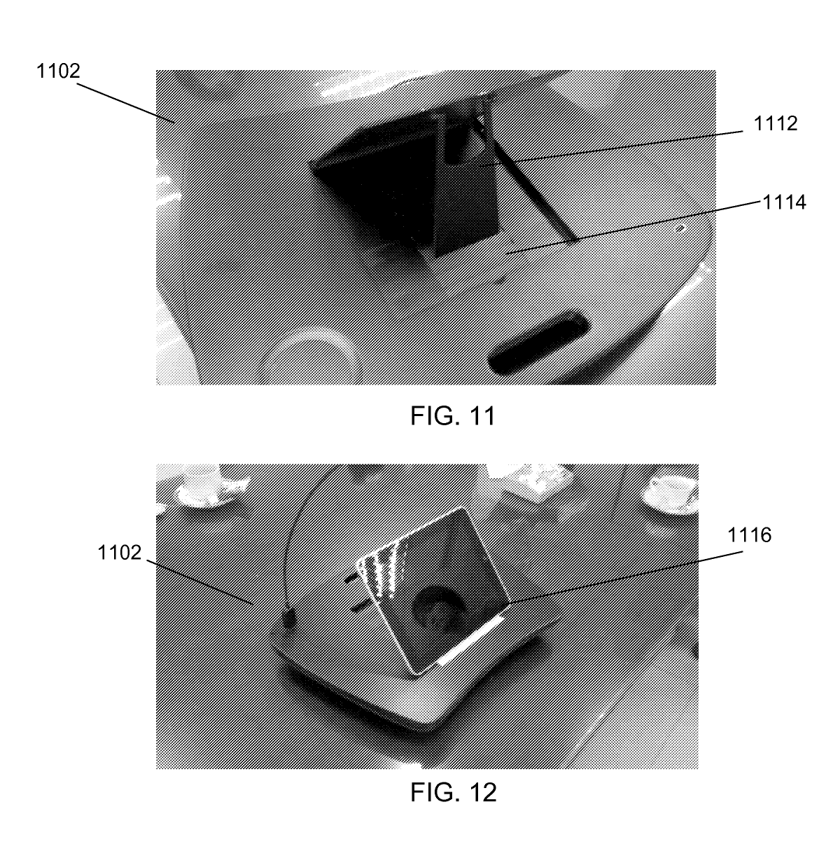

A view of a movable plate incorporated into a workstation is depicted in FIGS. 9-12. As shown, workstation 1102 is a standalone object having movable plate 1104, cup holder 1106, handle 1108, and outlet 1110. In some embodiments, workstation 1102 may include light 1111 which is configured to derive power from a battery pack located in workstation 1102 (not shown) after it has been inserted into outlet 1110 as shown in FIG. 10. Outlet 1110 is preferably a standard USB outlet. However, it should be obvious that outlet 1110 may be any type of outlet that is able to provide power to an external device.

FIGS. 10-12 show the movable plate 1104 in an open position. Movable plate 1102 is maintained in an open position through movable bracket 1112 residing in positioning slots 1114. After movable plate 1104 has been opened, a tablet personal computer 1116 can be placed on its surface as shown in FIG. 12 to allow for hands-free viewing and manipulation by a user.

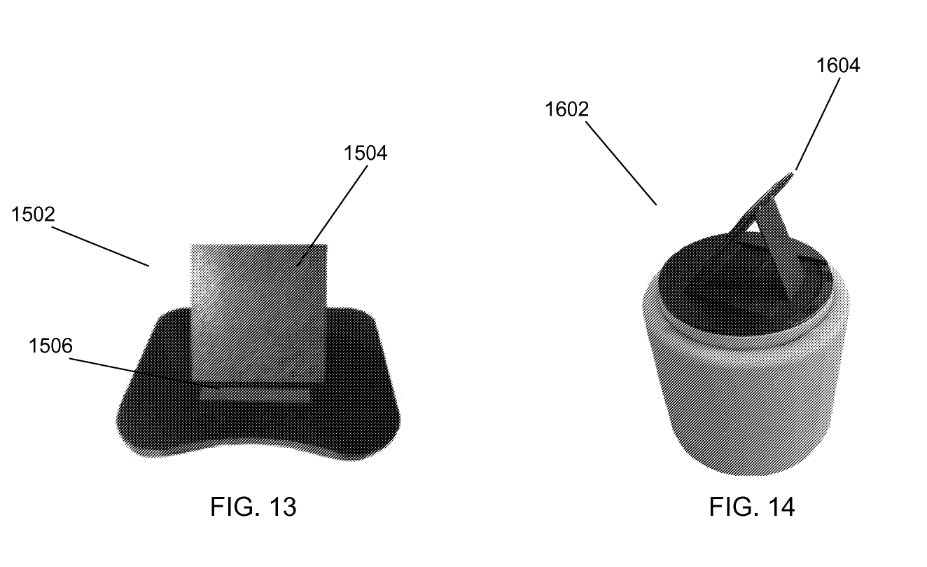

FIG. 13 depicts an alternative workstation 1502 similar to that of workstation 1102. However, in this configuration, movable plate 1504 further comprises ledge 1506 for retaining a tablet personal computer on the surface of movable plate 1504.

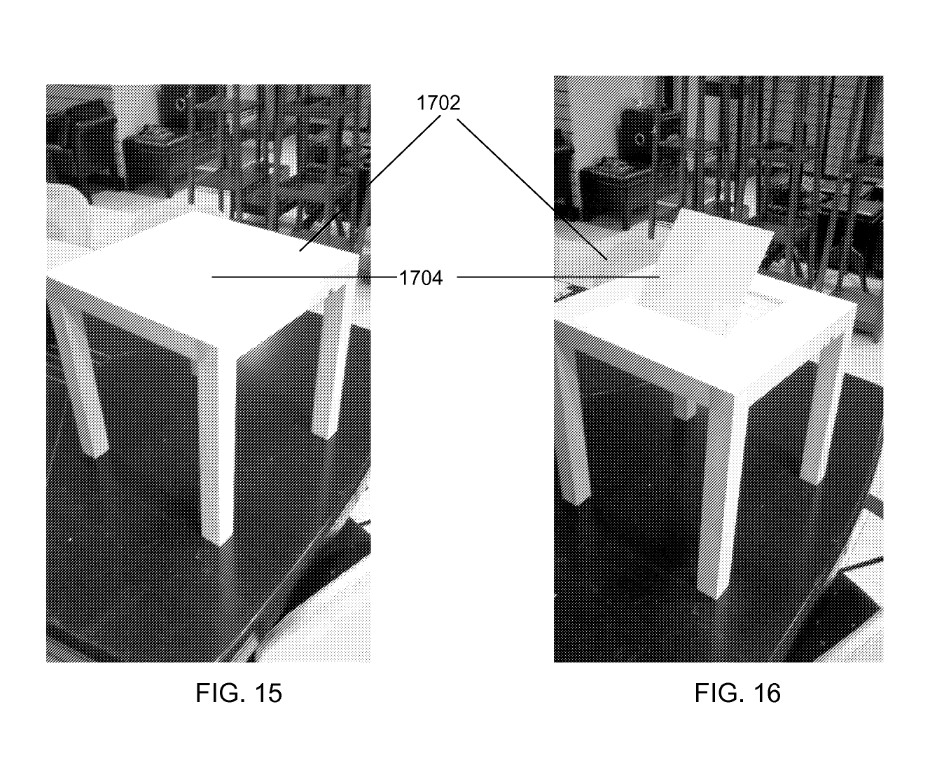

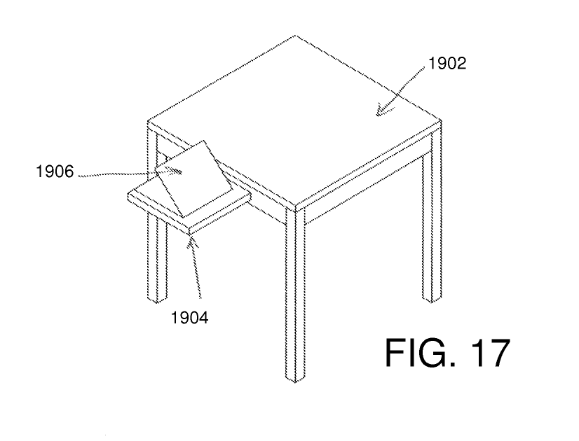

FIG. 14 depicts a stool 1602 having a movable plate 1604 in an open position. FIGS. 15 and 16 show a table 1702 having a movable plate 1704 movable between a closed position (FIG. 15) and an open position (FIG. 16). FIG. 17 shows an end table 1902 having a slidable leaf 1904 having a movable plate 1906.

As should be apparent from FIGS. 6-17, a movable plate can be incorporated into any piece of furniture having any flat surface such as, but not limited to, tables, end tables, desks, coffee tables, upholstered furniture such as ottomans, hassocks, sofas, benches and occasional furniture or specific use furniture such as a dinner tray, bed tray, or a tray which is rested on the lap., etc.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. An emplacement structure for a tablet personal computer, comprising:
a stool;
a box having an emplacement space configured to store the stool, wherein the box is opened with a combining slot;
a cover plate configured to be placed on the combining slot of the box and is opened with a holding slot, wherein a bottom of the cover plate is provided with plural positioning slots and a magnet; and
a movable plate having a movable bracket attached to the cover plate, wherein the movable bracket is inserted into one of the positioning slots to place the movable plate in an open position, and
wherein the movable plate is provided with a magnet that aligns with the magnet of the cover plate when the movable plate is in a closed position.

2. The emplacement structure for a tablet personal computer, according to claim 1, wherein the cover plate further comprises at least one folding plate pivotally attached to the cover plate.

3. The emplacement structure for a tablet personal computer, according to claim 2, wherein the at least one folding plate is provided with a magnet that aligns with a magnet on the movable plate.

4. The emplacement structure for a tablet personal computer, according to claim 1, wherein a side of the box comprises a speaker.

5. The emplacement structure for a tablet personal computer, according to claim 1, wherein a side of the box comprises a stereo

6. An emplacement structure comprising:
a surface; and
a movable plate located in a recess in the surface that is pivotable between an open position and a closed position, wherein the movable plate comprises:
a movable bracket pivotally attached to the movable plate,
wherein the movable plate is placed in an open position by inserting the movable bracket into positioning slots located in the recess.

7. The emplacement structure according to claim 6, wherein a top surface of the movable plate is flush with the surface of the emplacement structure when the movable plate is in the closed position.

8. The emplacement structure according to claim 6, wherein the movable plate further comprises an outlet and a power source.

9. The emplacement structure according to claim 8, wherein the outlet is a USB outlet.

10. The emplacement structure according to claim 6, wherein the surface of the emplacement structure further comprises a cup holder.

11. The emplacement structure according to claim 6, wherein the surface of the emplacement structure is substantially planar.

12. The emplacement structure according to claim 6, wherein the emplacement structure is incorporated into a piece of furniture.

13. The emplacement structure according to claim 12, wherein the furniture is a workstation, a desk, a table, a stool, or a chair.

14. The emplacement structure according to claim 6, wherein the surface comprises a non-skid strip, a recessed slot, or a raised strip.

15. An emplacement structure comprising:
a surface; and
a movable plate located in a recess in the surface that is pivotable between an open position and a closed position, wherein the movable plate comprises:
a movable bracket pivotally attached to recess in the surface,
wherein the movable plate is placed in an open position by inserting the movable bracket into positioning slots located on the movable plate.
